(19) United States
(12) Patent Application Publication
(10) Pub. No.: US 2002/0037373 A1
(43) Pub. Date: Mar. 28, 2002

(54) Material deposition

(76) Inventors: Kwang-Leong Choy, Cotteridge (GB); Wei Bai, Guilderland, NY (US)

Correspondence Address: Thomas J. Kowalski, Esq., FROMMER LAWRENCE & HAUG LLP, 745 Fifth Avenue, New York, NY, 10151, US

(21) Appl. No.: 09/750,517

(22) Filed: Dec. 28, 2000

Related U.S. Application Data
(63) Continuation-in-part of application No. PCT/GB99/02050, filed on Jun. 30, 1999.

(30) Foreign Application Priority Data
Jun. 30, 1998 (GB) GB 9814191.4

(51) Int. Cl. B05D 1/04; C23C 16/00

(52) U.S. Cl. 427/458; 427/248.1

(57) ABSTRACT

A method of material deposition of a desired material onto a substrate comprises the steps of: (i) depositing a surface-covering layer onto the substrate; (ii) depositing the desired material onto the surface-covering layer; and (iii) heating the substrate to a surface-covering removal temperature to remove at least some of the surface-covering layer. Steps (ii) and (iii) may be carried out together, so that the deposition of step (ii) may be carried out at least in part at the surface-covering-removal temperature.

This invention relates to material deposition.

Currently, there are few processing techniques available that can deposit dense coatings and films onto porous substrates. One such technique is the so-called Electrochemical Vapour Deposition method, but this suffers from the disadvantages that it is expensive and has a very low deposition rate.

Most of the more conventional vapour processing routes such as Chemical Vapour Deposition (CVD) and Physical Vapour Deposition (PVD) fail to deposit dense coatings onto porous substrates with well defined coating/substrate interface. This is because the vapour deposition precursors tend to penetrate into the porous substrates. If the surface pore size is bigger than about 1 μm, the deposition of a dense coating or film is even more difficult onto the porous substrate.

Similarly, it is difficult to produce dense coatings onto porous substrates with a well defined coating/substrate interface using wet chemical routes such as slip casting, tape casting, calendering and screen printing. This is especially true for large area production because the large shrinkages associated with the removal of polymeric binders and plasticizers in subsequent sintering steps reduces the quality of the coating. The coatings also tend to crack. This is especially apparent in the fabrication of thick and dense coatings onto porous substrates. Moreover, it is often difficult to retain adequate porosity within the porous structures of the substrates during the firing stage for densification of the films and coatings.

The ability to fabricate dense coatings and films onto porous substrates is very technologically important, especially for applications in the field of sensors and “clean” technologies such as fuel cells, gas separation etc. Therefore, there is an urgent need to develop cost-effective processing methods that can overcome the above fabrication problems.

M Liu et al, “Preparation of LSCF thin films, membranes and coatings”, J Mater. Res, Vol 10, No 12, December 1995, describes the preparation of thin film membranes of LSCF (La_{1-z}Sr_{z}Co_{1-y}Fe_{y}O₃₋ₓ) and SiO₂ onto porous Al₂O₃ substrates using dip coating (i.e. not a vapour deposition route) of polymer and sol solutions at about 200° C. followed by various heat treatment stages up to 750° C. The process involves applying a first coating using a precursor formed as a mixture of a polymer and SiO₂, followed by a second coating using a precursor formed as a mixture of LSCF and the polymer.

This invention provides a method of material deposition of a desired material onto a substrate, the method comprising the steps of:

(i) depositing a surface-covering layer onto the substrate;

(ii) depositing the desired material onto the surface-covering layer; and

(iii) heating the substrate to a surface-covering removal temperature to remove at least some of the surface-covering layer.

Embodiments of the invention can provide a fabrication technique to deposit dense coatings and films onto porous substrates cost-effectively. This is based on the deposition of a thin surface-covering film (e.g. a polymer film) followed by the deposition of the required dense coating. The polymer film can prevent the penetration of the vapour precursor into the porous substrate during the subsequent deposition of the dense coating or film.

The surface-covering material can have the properties of a sealant, in that it at least partially seals the pores of the substrate. In doing this, it can of course still be porous itself, although to achieve an advantageous result the pores of the deposited surface-covering material should be smaller than those of the substrate.

The surface-covering material is preferably substantially wholly or at least partly an organic material, preferably a polymer.

The materials are preferably applied by a vapour deposition technique, although not necessarily the same technique for the surface-covering material and the desired material.

The thin polymer film and the required dense coating can be deposited using the cost-effective Catalysed Electrostatic Assisted Vapour Deposition (ESAVD) approach, based on the deposition procedures and mechanism outlined in WO97/21848, or the Electrostatic Assisted Aerosol Jet Deposition (EAAJD) approach described in GB9900955.7. Both of these documents are hereby incorporated by reference. Furthermore, a copy of GB9900955.7 is filed herewith, to be placed on the public file by WIPO when the present PCT application is published.

This fabrication concept can thus enable dense coatings and films to be deposited onto “difficult” substrates such as porous substrates. In particular, dense coatings can be deposited onto porous substrates with a pore size as big as (for example) 100 μm, something which is difficult to achieve by any conventional fabrication concept using direct vapour deposition or wet chemical routes.

Production costs can be reduced, in comparison to an Electrochemical Vapour Deposition method, by using the preferred ESAVD or EAAJD methods. These methods also enable the polymer and the required dense coating to be fabricated in a single production process.

The technique (surface-covering/coating) has been used in prototype embodiments to fabricate dense yttria-stabilized-zirconia (YSZ) onto porous Lanthanum Strontium Manganite (LSM) using the ESAVD or EAAJD methods for application in solid oxide fuel cells, and dense Ce₁₋ₓGdₓO_{2-0.5} onto porous Ce₁₋ₓGd_{x2-0.5x} substrates for application in gas separation.

Thus, at least embodiments of this invention provide a method of vapour or other deposition of a desired material onto a substrate (e.g. a porous substrate) comprising: (i) depositing a surface-covering layer (e.g. a few microns thick, but could be within a large range of thickness) onto the substrate; and (ii) depositing the desired material onto the surface-covering layer.

Preferably, step (ii) is undertaken at a higher temperature than step (i), and it is particularly preferable that step (ii) is performed, at least in part, at a temperature sufficient to burn, evaporate or otherwise drive off the surface-covering layer. Indeed, in the finished article there may be little or no trace of the surface-covering remaining. The surface-covering can remain in place long enough to allow the deposition of the desired material.

Also, if the surface-covering is deposited at the lower temperature, its viscosity will be higher and hence it will tend to be absorbed less into the substrate.

Preferably the surface-covering is a polymer layer. The surface-covering may be deposited by various deposition techniques (e.g. vapour deposition, wet chemical deposition such as spray pyrolysis etc) as described earlier.

Preferably an intermediate layer of the substrate material is deposited over the surface-covering, but with a reduced pore size or denser structure with respect to the substrate. This step may be performed at the higher temperature to drive off the surface-covering, leaving the freedom to deposit the desired material (step (ii)) at another temperature.

The invention is particularly applicable to the fabrication of elements for use in fuel cells, but finds application in many other fields as well.

Although a later annealing or heating step can be employed to drive off the surface-covering, preferably steps (ii) and (iii) are carried out together, so that the deposition of step (ii) is carried out at least in part at the surface-covering removal temperature.

Although various materials can be used, preferably the surface-covering layer is at least in part a polymer layer or an organic/inorganic hybrid layer.

In order to enhance the adhesion of the desired material to the surface-covering, preferably an additional step, between steps (i) and (ii), is carried out to deposit an interlayer between the surface-covering layer and the desired material. In some embodiments, the interlayer comprises a layer of the substrate material having a smaller pore size and/or a denser structure (i.e. a better receiving surface for the desired material) than that of the substrate. In other embodiments, the interlayer comprises one or more layers of a mixture of the surface-covering material and the desired material.

Indeed, in some preferred embodiments, to give a more gradual transition between the surface-covering and the desired material, the interlayer comprises a plurality of layers of a mixture of the surface-covering material and the desired material, the layers having a proportion of the desired material with respect to the surface-covering material which generally increases as further such layers are deposited. Preferably the deposition temperature generally increases for the deposition of each layer of the interlayer.

The method is suitable for use with different materials for the substrate and the desired (deposited) material, but it is particularly suitable for use where the desired material has substantially the same chemical constituents (although potentially a different stoichiometry) as the substrate.

The invention also provides a method of material deposition of a desired material onto a substrate, the method comprising the steps of:

(i) depositing a surface-covering layer onto the substrate;

(ii) depositing an interlayer of substrate material onto the surface-covering layer, the interlayer having a denser-structure and/or a smaller pore size than the substrate; and

(iii) depositing the desired material onto the interlayer.

Embodiments of the invention will now be described by way of example with-reference to the accompanying drawings, throughout which like parts are referred to by like references, and in which:

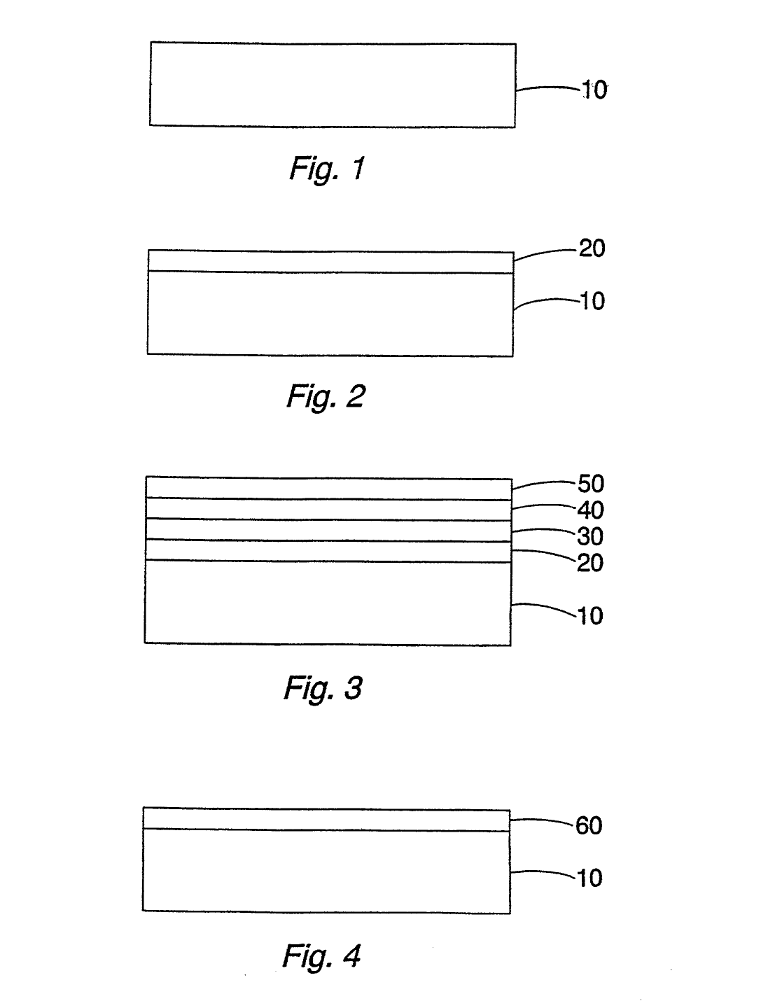

FIG. 1 schematically illustrates a cerium gadolinium oxide substrate;

FIG. 2 schematically illustrates the application of a first surface-covering layer to the substrate of FIG. 1;

FIG. 3 schematically illustrates the application of a graded composition interlayer structure;

FIG. 4 schematically illustrates the structure after application of a final CGO layer; and

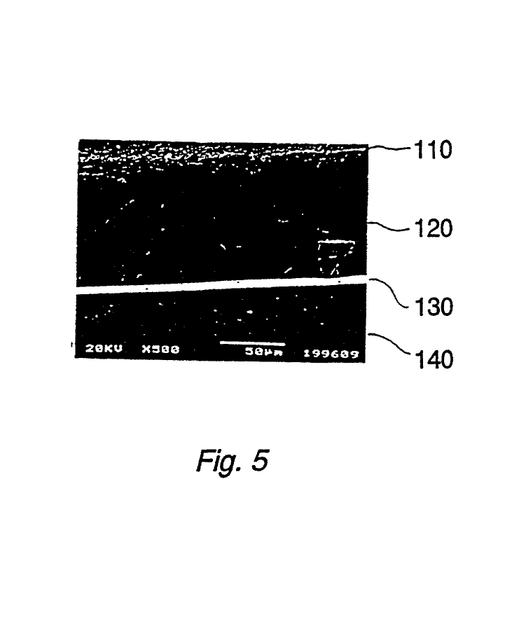

FIG. 5 is an electromicrograph showing an LSM substrate on which YSZ and NiO/YSZ layers have been deposited using an interlayer of reduced pore size.

A first example described with reference to FIGS. 1 to 4 (which are not to scale) relates to the fabrication of dense Ce₁₋ₓGdₓO_{2-0.5x} (CGO) films onto porous CGO substrates using ESAVD). FIG. 1 schematically illustrates the CGO substrate 10.

A polymer layer 20 (FIG. 2) is deposited as the surface-covering layer. This is carried out by ESAVD using a 0.005 molar solution of ethylene glycol (Mn=1500) dissolved in a solvent comprising 70% ethanol and 30% de-ionised water. The deposition is carried out at relatively low temperatures such as 225° C. The thickness of the film can be controlled by varying the deposition time, the electric field strength, the concentration of ethylene glycol etc. The desired film thickness is about 0.5 μm for the present exemplary case where the substrate has a pore size of about 0.2 μm. To an extent, the appropriate film thickness depends on the pore size of the porous substrate.

The precursor used in the deposition process is then changed gradually (rather than abruptly) from an ethylene glycol solution to a CGO solution to provide a graded transition between the two materials. For example, a series of precursors could be used having the following ratios of CGO to ethylene glycol (EG):

| CGO:EG ratio | Notes | Ref-see FIGS. 2 to 4 |
|---|---|---|
| 0 | i.e. no CGO, just ethylene glycol | 20 |
| 0.25 | mainly ethylene glycol | 30 |
| 1.0 | — | 40 |
| 3.0 | mainly CGO | 50 |
| ˜infinity | i.e. no ethylene glycol, just CGO. | 60 |

The CGO layer 60 is then applied. The CGO precursor is a stable 0.05 molar precursor solution formed of cerium acetate and gadolinium acetate in the same type of solvent as that described above (70% ethanol, 30% water). The solution is prepared according to the stoichiometry requirements of the desired Ce₁₋ₓGdₓO_{2-0.5x} films. Acetic acid is used as a pH-controlling catalyst, with a desired pH being in the range of 2.0-2.5.

Each step in the above process can be carried out at an increased temperature over the previous step. For example, the “0.25” ratio solution could be deposited at 240° C., the “1.0” ratio solution at 255° C. and the “3.0” ratio solution at 270° C. The deposition of CGO can then be carried out at 400° C. This temperature is high enough to burn off, evaporate or otherwise disperse the surface-covering material previously deposited on the substrate, resulting in the structure shown in FIG. 4 where the deposited CGO layer remains on the substrate 10. Alternatively, the completed structure could be annealed at a temperature high enough to disperse the surface-covering layer.

Of course, it is not essential to the invention that absolutely all traces of the surfacecovering are dispersed or removed. Generally, though, at least a majority (often a large majority) of the surface-covering can be removed in this way. In fact, it can be highly useful in some cases to ensure that all of the surface-covering material is removed to avoid the presence of impurities in the resulting (desired) film or layer which can adversely influence the structural or other properties of that layer. So, by raising the substrate or deposition temperature to a suitable level, it can be ensured that substantially all of the surface-covering material is driven off.

The procedural details of the deposition are as follows. Each of the precursor materials containing at least some ethylene glycol is deposited for a period of about 5 minutes. The final CGO deposition is carried out for a period of about 10 minutes. The electric field strength used is 8-15 kV with a flow rate of 10 ml/hour and a nozzle to substrate distance of between 2 and 5 cm. However, it will be clear that many other deposition regimes, materials, solvents or solution concentrations could be used instead.

In particular, it will be appreciated that the surface-covering layer can be for example a polymer layer or an organic/inorganic hybrid layer. The surface-covering and subsequent layers, including those described below, may be deposited by various means such as ESAVD, spray pyrolysis, chemical vapour deposition, physical vapour deposition etc. However, ESAVD has the advantage of a high deposition rate for the surface-covering and the desired material, allowing a high deposition efficiency in a single step by varying the precursor solution and processing parameters.

The surface-covering could be a composite layer comprising fine reinforcements (e.g. metal, ceramic or polymer) in a polymer or organic/inorganic hybrid matrix.

The deposited material (i.e. the material to be deposited over the surface-covering layer) can be the same as or different to the substrate material.

Optionally a so-called interlayer of the substrate material can be deposited over the surface-covering but with a reduced pore size or a denser structure with respect to the substrate. Alternatively (or additionally), an interlayer of the desired material or a compositionally graded layer of the desired and surface-covering materials can be deposited over the surface-covering layer.

FIG. 5 is an electromicrograph of a cross section of a prototype structure formed using the techniques described above. The text across the bottom of the electromicrograph provides information about the microscopy and display process used, and reads:

20 kV (accelerating voltage used in the microscope)

X500 (display magnification)

50 μm (an indication of scale, referring to the length of the horizontal bar)

199609 (a serial number of the experiment) An LSM substrate 140 having a pore size of the order of about 0.2 μm had a polymer surface-covering layer deposited on it using ESAVD. The polymer material was ethylene glycol and the layer was about 0.5 μm thick, but the polymer layer is no longer shown on FIG. 5 as it was burned off or otherwise dispersed during subsequent deposition steps.

Over the surface-covering layer a layer 130 of the substrate material (LSM) having a smaller pore size than the substrate was deposited. This layer is a few microns thick. Over the layer 130, a layer 120 of dense YSZ about 75 μm thick is deposited, and over that, a layer 110 of NiO/YSZ is deposited.

So, FIG. 5 shows a layer of YSZ and a final layer of NiO/YSZ deposited onto a porous LSM substrate, something not easily achievable (if achievable at all) using previous techniques.

It will be appreciated that the present techniques are not of course limited to the materials, temperatures or compositions given in the exemplary embodiments.

1. A method of material deposition of a desired material onto a substrate, the method comprising the steps of:
(i) depositing a surface-covering layer onto the substrate;
(ii) depositing the desired material onto the surface-covering layer; and
(iii) heating the substrate to a surface-coverig removal temperature to remove at least some of the surface-covering layer.

2. Apparatus according to claim 1, in which steps (ii) and (iii) are carried out together, so that the deposition of step (ii) is carried out at least in part at or above the surface-covering removal temperature.

3. A method according to claim 1 or claim 2, in which the substrate is a porous substrate.

4. A method according to any one of the preceding claims, in which the surface-covering layer is at least in part a polymer layer.

5. A method according to any one of claims 1 to 3, in which the surface-covering layer comprises an organic/inorganic hybrid layer.

6. A method according to any one of the preceding claims, comprising the step, between steps (i) and (ii), of:
depositing an interlayer between the surface-covering layer and the desired material.

7. A method according to claim 6, in which the interlayer comprises a layer of the substrate material having a smaller pore size and/or a denser structure than that of the substrate.

8. A method according to claim 6, in which the interlayer comprises one or more layers of a mixture of the surface-covering material and the desired material.

9. A method according to claim 8, in which the interlayer comprises a plurality of layers of a mixture of the surface-covering material and the desired material, the layers having a proportion of the desired material with respect to the surface-covering material which generally increases as further such layers are deposited.

10. A method according to claim 9, in which the deposition temperature generally increases for the deposition of each layer of the interlayer.

11. A methQd according to any one of the preceding claims, in which the surface-covering layer is deposited by electrostatic spray-assisted vapour deposition or electrostatic assisted aerosol jet deposition.

12. A method according to any one of the preceding claims, in which the desired material is deposited by electrostatic spray-assisted vapour deposition or electrostatic assisted aerosol jet deposition.

13. A method according to any one of the preceding claims, in which the desired material has substantially the same chemical constituents as the substrate.

14. A method of material deposition of a desired material onto a substrate, the method comprising the steps of:
(i) depositing a surface-covering layer onto the substrate;
(ii) depositing an interlayer of substrate material onto the surface-covering layer, the interlayer having a denser structure and/or a smaller pore size than the substrate; and
(iii) depositing the desired material onto the interlayer.
